(19) United States
(12) Patent Application Publication
(10) Pub. No.: US 2004/0206387 A1
(43) Pub. Date: Oct. 21, 2004

(54) Method for fabricating a Fe-Si based thin film, and Fe-Si based thin film

(75) Inventor: Hiroshi Funakubo, Kawasaki City (JP)

Correspondence Address: OLIFF & BERRIDGE, PLC, P.O. BOX 19928, ALEXANDRIA, VA, 22320, US

(73) Assignee: TOKYO INSTITUTE OF TECHNOLOGY, Tokyo (JP)

(21) Appl. No.: 10/758,097

(22) Filed: Jan. 16, 2004

(30) Foreign Application Priority Data
Apr. 10, 2003 (JP) 2003-106,784

(51) Int. Cl. H01L 35/12; H01L 21/00; H01L 21/20; H01L 35/20

(52) U.S. Cl. 136/236.1; 438/478; 438/97; 136/239; 136/261

(57) ABSTRACT

A substrate of which the crystal planes are orientated perpendicular to a main surface thereof and made of the same kind of ion is prepared. Then, film forming operation is performed on the main surface of the substrate to epitaxially grow a Fe—Si based thin film thereon.

### BACKGROUND OF THE INVENTION

1. Field of the Invention

This invention relates to a method for fabricating a Fe—Si based thin film and the Fe—Si based thin film which are preferably usable for a solar cell, a composite electric power generating element composed of a solar cell and a thermoelectric element, a light emitting device or a spintronics element.

2. Description of the prior art

It is confirmed that β-FeSi₂ exhibits electroluminescence at a wavelength of 1.5 μm which can be utilized in the present optical communication at room temperature. Moreover, since Fe—Si based material can contain Fe₃Si phase, if the composition of the Fe—Si based material is controlled appropriately, the resultant device can exhibit specific performances which are balanced optically, electronically and magnetically. In this point of view, such an attempt is made as to epitaxially grow the Fe—Si based thin film, but as of now, such an epitaxial growing technique has not yet established.

### SUMMERY OF THE INVENTION

It is an object of the present invention to establish the epitaxial growing technique for the Fe—Si based thin film.

For achieving the above object, this invention relates to a method for fabricating a Fe—Si based thin film, comprising the steps of:

preparing a substrate of which the crystal planes are orientated perpendicular to a main surface thereof and made of the same kind of ion, and

performing film forming operation on the main surface of the substrate to epitaxially grow a Fe—Si based thin film thereon.

This invention also relates to a method for fabricating a Fe—Si based thin film, comprising the steps of:

preparing a given substrate,

forming, on the substrate, a buffer layer of which the crystal planes are orientated perpendicular to a main surface thereof and made of the same kind of ion, and

performing film forming operation on the main surface of the buffer layer to epitaxially grow a Fe—Si based thin film thereon.

The inventors had intensely studied to achieve the above-mentioned object. As a result, they found out that a substrate or a buffer layer of which the crystal planes are orientated perpendicular to the main surface thereof and made of the same kind of ion is prepared, and film forming operation is carried out onto the main surface thereof, to realize the epitaxial growth of the Fe—Si based thin film, which is difficult by a conventional technique as mentioned above.

FIGS. 1 and 2 are explanatory views for the orientation of a substrate to be employed in the present invention. FIGS. 1 and 2 illustrate the cross sections of the substrate, taken on lines along the main surface of the substrate. In the present invention, as mentioned above, it is required that in the substrate, a plurality of crystal planes thereof are orientated perpendicular to the main surface thereof and made of the same kind of ion, which is illustrated in FIG. 1. In FIG. 1, the ions of the same kind are drawn by the white dots.

If the substrate is made of different kinds of ions, as illustrated in FIG. 2, the above-mentioned requirement of the present invention can not be satisfied, so that the epitaxial growth of the Fe—Si based thin film can not be realized. In FIG. 2, the ions of the different kinds are drawn by the white dots and the black dots.

If a given buffer layer is employed, instead of the substrate, it is required that in the buffer layer, a plurality of crystal planes thereof are orientated perpendicular to the main surface thereof and made of the same kind of ion, as illustrated in FIGS. 1 and 2 and as mentioned above.

In the present invention, if the substrate or the buffer layer which can satisfy the requirement of the present invention as mentioned above is employed, the epitaxial growth of the Fe—Si based thin film can be realized. Therefore, a new device which can function on the optical, electrical and magnetic features of the Fe—Si based thin film can be provided. For example, a new kind of light emitting device can be provided. In addition, a new device which is balanced optically, electrically and magnetically can be provided.

In a preferred embodiment of the present invention, the difference in lattice constant between the substrate or the buffer layer and the Fe—Si based thin film is set to 16% or below, preferably within −6% to 16%. In this case, the epitaxial growth of the Fe—Si based thin film can be realized easily. The difference in lattice constant is standardized by the lattice constant of the substrate or the buffer layer. That is, if the lattice constant of the substrate or the buffer layer is defined by ds and the lattice constant of the Fe—Si based thin film is defined by df, the difference in lattice constant can be represented by the equation as follows: (df−ds)/ds−100.

Other features and advantages of the present invention will be described hereinafter.

### BRIEF DESCRIPTION OF THE DRAWINGS

For better understanding of the present invention, reference is made to the attached drawings, wherein

FIG. 1 is an explanatory view for the orientation of a substrate to be employed in the present invention,

FIG. 2 is another explanatory view for the orientation of the substrate to be employed in the present invention,

FIG. 3 is a schematic view illustrating the crystal structure of a Fe—Si based thin film which is epitaxially grown according to the present invention,

FIG. 4 is another schematic view illustrating the crystal structure of the Fe—Si based thin film which is epitaxially grown according to the present invention,

FIG. 5 is an explanatory view for the orientation of the Fe—Si based thin film which is orientated commensurate with the (100) plane, and

FIG. 6 is another explanatory view for the orientation of the Fe—Si based thin film which is orientated commensurate with the (100) plane.

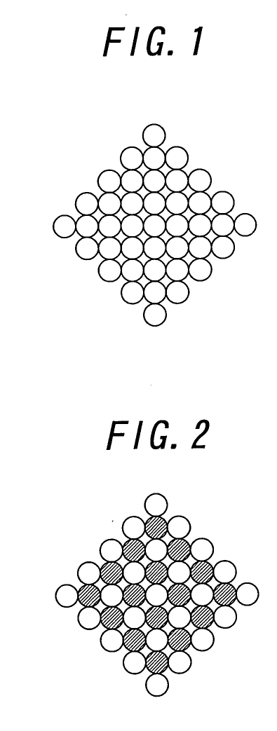

### DESCRIPTION OF THE PREFERRED EMBODIMENTS

This invention will be described in detail by way of examples with reference to the accompanying drawings.

In the present invention, it is required that a substrate or a buffer layer of which the crystal planes are orientated perpendicular to the main surface and made of the same kind of ion is employed. Any kind of substrate or buffer layer can be employed only if the requirement of the present invention is satisfied. It is desired, however, that the difference in lattice constant between the substrate or the buffer layer and the Fe—Si based thin film is set to 16% or below, preferably within −6% to 16%.

In this point of view, the substrate or the buffer layer may be made of (100)Si, (111)Si, (100)Y₂O₃-ZrO₂, (111)Y₂O₃-ZrO₂, (001)Al₂O₃, (100)CeO₂ or (111)CeO₂. In addition, the substrate or the buffer layer may be made of composite layer structure of (100)Y₂O₃-ZrO₂/(100)Si. In this case, the intended Fe—Si based thin film can be epitaxially and easily grown on the substrate or the buffer layer. However, another kind of material may be employed only if the above-mentioned requirement of the present invention is satisfied.

The epitaxial growth of the Fe—Si based thin film can be realized by means of a conventional film forming technique such as sputtering, deposition and CVD. If the substrate or the buffer layer is made of above-mentioned preferable material such as (100) Si, the epitaxial growth of the Fe—Si based thin film can be realized by means of sputtering, particularly RF magnetron sputtering or CVD. The use of sputtering can simplify the control of the film forming condition and the large-scaled film formation, and enhance the reproducibility, to realize the industrial mass production of the Fe—Si based thin film.

In the fabrication of the Fe—Si based thin film utilizing the conventional film forming technique, it is required to apply some energy to the Fe—Si based thin film under fabrication. Simply, therefore, some thermal energy is applied to the Fe—Si based thin film under fabrication by heating the substrate or the buffer layer. In the use of sputtering or CVD, the substrate or the buffer layer is heated within 600-900° C., preferably within 700-850° C. In this case, the epitaxial growth of the Fe—Si based thin film can be realized irrespective of the kind of the substrate or the buffer layer only if the requirement for the substrate or the buffer layer to be employed is satisfied according to the present invention.

The resultant Fe—Si based thin film fabricated through epitaxial growth can contain a crystal structure made of a plurality of crystal planes, each plane being made of Fe or Si.

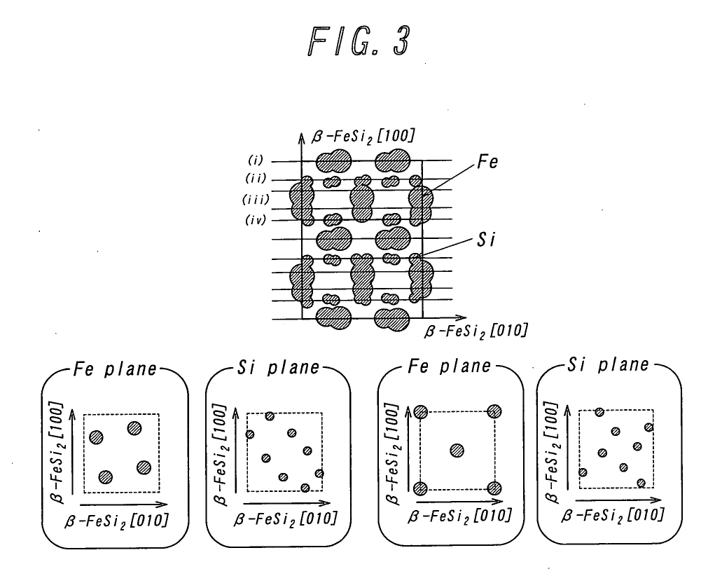

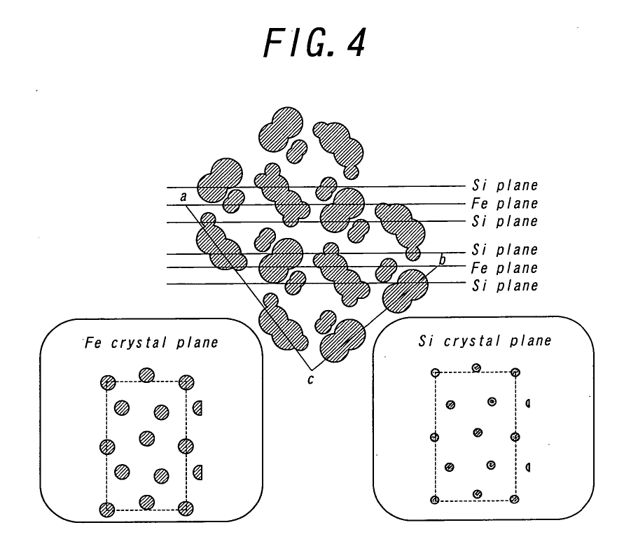

FIGS. 3 and 4 are schematics view illustrating the crystal structure of the Fe—Si based thin film. FIG. 3 illustrates the crystal plane in the crystal structure of the Fe—Si based thin film which is orientated commensurate with the (100) plane, and FIG. 4 illustrates the crystal plane in the crystal structure of the Fe—Si based thin film which is orientated commensurate with the (110)/(101) plane.

As illustrated in FIG. 3, the Fe—Si based thin film orientated commensurate with the (100) plane contains crystal planes (i) and (iii) made of Fe and crystal planes (ii) and (iv) made of Si which are successively stacked, respectively. In other words, the Fe—Si based thin film can contain the crystal structure where the Fe crystal planes and the Si crystal planes are alternately stacked, respectively.

As illustrated in FIG. 4, on the other hand, the Fe—Si based thin film orientated commensurate with the (110)/(101) plane also contain the crystal structure where the Fe crystal planes and Si crystal planes are alternately stacked, respectively.

The Fe—Si based thin film orientated commensurate with the (100) plane as illustrated in FIG. 3 can be fabricated by utilizing the substrate or the buffer layer made of (100) Si, (100)Y₂O₃-ZrO₂, (001)Al₂O₃ or (100)CeO₂, for example. The Fe—Si based thin film orientated commensurate with the (111)/(101) plane as illustrated in FIG. 4 can be fabricated by utilizing the substrate or the buffer layer made of (111)Si, (111)Y₂O₃-ZrO₂ or (111)CeO₂, for example.

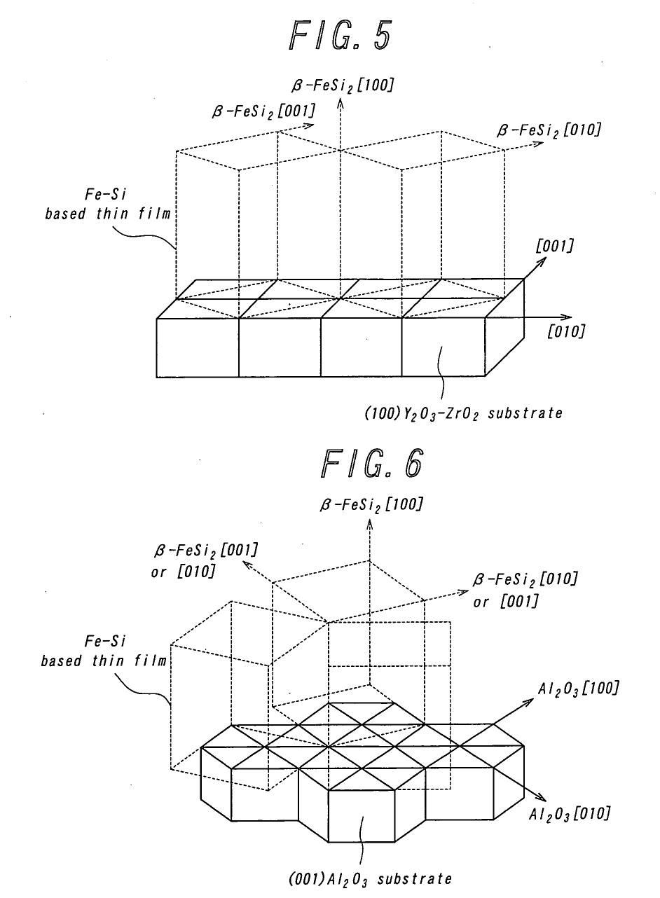

FIGS. 5 and 6 are explanatory views for the orientation of the Fe—Si based thin film which is orientated commensurate with the (100) plane. For example, the use of the (111)Y₂O₃-ZrO₂ substrate or buffer layer can provide the Fe—Si based thin film with two rotational symmetry. The use of (001)Al₂O₃ substrate or buffer layer can provide the Fe—Si based thin film with three rotational symmetry.

### EXAMPLE

(Example)

According to the present invention were prepared a (100) Si substrate, a (111)Si substrate, a (100)Y₂O₃-ZrO₂ substrate, a (111)Y₂O₃-ZrO₂ substrate, and a (001)Al₂O₃ substrate, on which film forming operation were carried out by means of RF sputtering utilizing a FeSi₂ target with a dimension of two inches. The distance between each substrate and the target was set to 12 cm, and the input RF power was set to 30 W. The sputtering operation was performed under Ar atmosphere kept at a pressure of 3×10⁻³ Torr. Then, in the sputtering operation, the temperature of each substrate was set to 735° C., and the film forming rate was set to 0.8 nm/min.

With the examination of crystal structure, in the use of the (100) Si substrate, a (100)Y₂O₃-ZrO₂ substrate and a (001)Al₂O₃ substrate, the resultant Fe—Si based thin film was orientated commensurate with the (100) plane. In the use of the (111)Si substrate and a (111)Y₂O₃-ZrO₂ substrate, the resultant Fe—Si based thin film was orientated commensurate with the (110)/(101) plane.

(Comparative Example)

Different from the present invention, a (100) MgO substrate, a (111) MgO substrate, a (100) MgAl₂O₄ substrate, a (100) SrTiO₃ substrate, a (111) SrTiO₃ substrate, a (102) Al₂O₃ substrate, (110) Al₂O₃ substrate and a (110) Y₂O₃-ZrO₂ substrate were prepared. Then, film forming operation was performed on each substrate in the same manner as in Example. As a result, no epitaxial grown Fe—Si based thin film was fabricated.

Instead of the substrates in Example and Comparative Example, like buffer layers were prepared. In this case, whether the epitaxial grown Fe—Si based thin film can be fabricated or not depended on the kinds of the buffer layers. In other words, if the buffer layer to satisfy the requirement of the present invention was employed, the epitaxial grown Fe—Si based thin film can be fabricated. In contrast, if the buffer layer not to satisfy the requirement of the present invention was employed, no epitaxial grown Fe—Si based thin film can be fabricated.

Although the present invention was described in detail with reference to the above examples, this invention is not limited to the above disclosure and every kind of variation and modification may be made without departing from the scope of the present invention.

What is claimed is:

1. A method for fabricating a Fe—Si based thin film, comprising the steps of:
preparing a substrate of which the crystal planes are orientated perpendicular to a main surface thereof and made of the same kind of ion, and performing film forming operation on said main surface of said substrate to epitaxially grow a Fe—Si based thin film thereon.

2. The fabricating method as defined in claim 1, wherein the difference between said substrate and said Fe—Si based thin film is set to 16% or below.

3. The fabricating method as defined in claim 2, wherein the difference between said substrate and said Fe—Si based thin film is set within −6% to 16%.

4. The fabricating method as defined in claim 1, wherein said Fe—Si based thin film is fabricated by means of RF magnetron sputtering or CVD.

5. The fabricating method as defined in claim 4, wherein said substrate is heated within 600-900° C.

6. The fabricating method as defined in claim 1, wherein said substrate is made of (100) Si, (111)Si, (100)Y₂O₃-ZrO₂, (111)Y₂O₃-ZrO₂, (001)Al₂O₃, (100)CeO₂ or (111)CeO₂.

7. The fabricating method as defined in claim 1, wherein said Fe—Si based thin film contains a crystal structure where Fe crystal planes and Si crystal planes are alternately stacked, respectively.

8. The fabricating method as defined in claim 7, wherein said substrate is made of (111)Si, (111)Y₂O₃-ZrO₂ or (111)CeO₂, and said Fe—Si based thin film is orientated commensurate with the (110)/(101) plane thereof.

9. The fabricating method as defined in claim 7, wherein said substrate is made of (100) Si, (100)Y₂O₃-ZrO₂, (001)Al₂O₃ or (100)CeO₂, and said Fe—Si based thin film is orientated commensurate with the (100) plane thereof.

10. The fabricating method as defined in claim 9, wherein said substrate is made of (100)Y₂O₃-ZrO₂, and said Fe—Si based thin film is epitaxially grown in two rotational symmetry.

11. The fabricating method as defined in claim 9, wherein said substrate is made of (001)Al₂O₃, and said Fe—Si based thin film is epitaxially grown in three rotational symmetry.

12. A method for fabricating a Fe—Si based thin film, comprising the steps of:
preparing a given substrate, forming, on said substrate, a buffer layer of which the crystal planes are orientated perpendicular to a main surface thereof and made of the same kind of ion, and performing film forming operation on said main surface of said buffer layer to epitaxially grow a Fe—Si based thin film thereon.

13. The fabricating method as defined in claim 12, wherein the difference between said buffer layer and said Fe—Si based thin film is set to 16% or below.

14. The fabricating method as defined in claim 13, wherein the difference between said buffer layer and said Fe—Si based thin film is set within −6% to 16%.

15. The fabricating method as defined in claim 12, wherein said Fe—Si based thin film is fabricated by means of RF magnetron sputtering or CVD.

16. The fabricating method as defined in claim 15, wherein said buffer layer is heated within 600-900° C.

17. The fabricating method as defined in claim 12, wherein said buffer layer is made of (100)Si, (111)Si, (100)Y₂O₃-ZrO₂, (111)Y₂O₃-ZrO₂, (001)Al₂O₃, (100)CeO₂ or (111)CeO₂.

18. The fabricating method as defined in claim 12, wherein said Fe—Si based thin film contains a crystal structure where Fe crystal planes and Si crystal planes are alternately stacked, respectively.

19. The fabricating method as defined in claim 18, wherein said buffer layer is made of (111)Si, (111)Y₂O₃-ZrO₂ or (111)CeO₂, and said Fe—Si based thin film is orientated commensurate with the (110)/(101) plane thereof.

20. The fabricating method as defined in claim 18, wherein said buffer layer is made of (100)Si, (100)Y₂O₃-ZrO₂, (001)Al₂O₃ or (100)CeO₂, and said Fe—Si based thin film is orientated commensurate with the (100) plane thereof.

21. The fabricating method as defined in claim 20, wherein said buffer layer is made of (100)Y₂O₃-ZrO₂, and said Fe—Si based thin film is epitaxially grown in two rotational symmetry.

22. The fabricating method as defined in claim 20, wherein said buffer layer is made of (001)Al₂O₃, and said Fe—Si based thin film is epitaxially grown in three rotational symmetry.

23. A Fe—Si based thin film, wherein Fe crystal planes and Si crystal planes are alternately stacked, respectively.

24. The Fe—Si based thin film as defined in claim 23, which is orientated commensurate with the (110)/(101) plane thereof.

25. The Fe—Si based thin film as defined in claim 23, which is orientated commensurate with the (100) plane thereof.

26. The Fe—Si based thin film as defined in claim 25, which is orientated in two rotational symmetry.

27. The Fe—Si based thin film as defined in claim 25, which is orientated in three rotational symmetry.
